(19) United States
(12) Patent Application Publication
(10) Pub. No.: US 2026/0157207 A1
(43) Pub. Date: Jun. 4, 2026

(54) SEMICONDUCTOR ASSEMBLIES WITH PROTECTIVE LAYERS, INCLUDING PROTECTIVE LAYERS WITH REMOVABLE PAD COVERINGS, AND ASSOCIATED METHODS FOR MAKING AND USING THE SAME

(71) Applicant: Micron Technology, Inc., Boise, ID (US)

(72) Inventors: Hong Wan Ng, Singapore (SG); Kelvin Tan Aik Boo, Singapore (SG); Seng Kim Ye, Singapore (SG); Chin Hui Chong, Singapore (SG)

(21) Appl. No.: 19/352,985

(22) Filed: Oct. 8, 2025

Related U.S. Application Data
(60) Provisional application No. 63/727,540, filed on Dec. 3, 2024.

(51) Int. Cl. H10W 70/69; H10W 70/05; H10W 70/65

(52) U.S. Cl. CPC H10W 70/69; H10W 70/05; H10W 70/65

(57) ABSTRACT

Semiconductor assemblies with protective layers, including protective layers with removable pad coverings, and associated methods for making and using the same are disclosed herein. In one embodiment, a semiconductor assembly comprises (i) a substrate having a top side and a bottom side opposite the top side; (ii) a pad disposed within the substrate at a location between the top side and the bottom side, and accessible via the bottom side of the substrate; (iii) a protective layer at the bottom side of the substrate; and (iv) an isolation feature at the bottom side of the substrate and configured to separate at least part of the pad covering from the substrate. The protective layer can include a pad covering disposed over at least a portion of a bottom surface of the pad such that at least the portion of the bottom surface is unexposed through the bottom side of the substrate.

### CROSS-REFERENCE TO RELATED APPLICATION(S)

The present application claims priority to U.S. Provisional Patent Application No. 63/727,540, filed December 3, 2024, the disclosure of which is incorporated herein by reference in its entirety.

### TECHNICAL FIELD

The present disclosure generally relates to semiconductor device assemblies, and more particularly relates to semiconductor packaging.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are "packaged" to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic partial plan view of a semiconductor device assembly configured in accordance with various embodiments of the present technology.

FIG. 2 is a cross-sectional side view of a semiconductor device assembly (i) having a removable pad covering and (ii) configured in accordance with various embodiments of the present technology.

FIG. 3A is a simplified detail view of a removable pad covering configured in accordance with various embodiments of the present technology.

FIG. 3B is simplified detail view of another removable pad covering configured in accordance with various embodiments of the present technology.

FIG. 4 is a simplified schematic partial plan view of a semiconductor device assembly configured in accordance with various embodiments of the present technology.

FIG. 5 is a cross-sectional side view of a semiconductor device assembly configured in accordance with various embodiments of the present technology.

FIG. 6A is a simplified detail view of a pad covering configured in accordance with various embodiments of the present technology.

FIG. 6B is a simplified detail view of another pad covering configured in accordance with various embodiments of the present technology.

FIG. 7 is a schematic view showing a system that includes a semiconductor device assembly configured in accordance with various embodiments of the present technology.

FIG. 8 is a flow chart illustrating a method of making a semiconductor device assembly in accordance with various embodiments of the present technology.

### DETAILED DESCRIPTION

The electronics industry relies on continuous innovation in the field of semiconductor packaging to meet the global need for higher-functioning technology. This demand calls for increasingly complicated assemblies of semiconductor devices, which may diverge in terms of plan area, thickness, connection methodology, etc. One approach to accommodate the packaging of such varied devices into a single assembly is to include test pads, which can provide specific points of contact for test probes (e.g., for testing or debugging), ensuring the semiconductor devices operate correctly and meet performance standards. Current designs of test pads, however, have many disadvantages.

For example, current test pad designs use exposed copper plated with gold, combining copper’s excellent conductivity with gold’s (i) resistance to corrosion and (ii) ability to form strong, reliable bonds with other materials. When two metals with differing voltage potentials are in contact, however, the risk of galvanic corrosion is increased, particularly given the potential exposure to moisture during semiconductor manufacture processes (e.g., from unremoved rinse water or cleaning solution, or environmental humidity and moisture). Continuing with the above example, gold has a higher voltage potential than copper. Thus, galvanic corrosion can cause the copper of a test pad to rapidly corrode as the gold portion of the pad steals copper ions in the electrolyte solution. As a result, the galvanic corrosion can degrade the electrical connections provided by the test pad and therefore the overall reliability of the semiconductor device.

To address these drawbacks and others, various embodiments of the present disclosure provide semiconductor device assemblies that include protective layers configured to protect test pads from damage or degradation. The protective layers can include pad coverings. In some embodiments, the pad coverings can be removable. For example, when the test pads are needed for a test procedure, the removable pad coverings can be stripped away. That is, the removable pad coverings can be configured as flaps that are reversibly strippable. In some embodiments, when the test procedure has completed, the removable pad coverings can be reapplied. The protective layer can additionally include a remainder portion that is disposed at a bottom side of a substrate of the assembly. The remainder portion can remain at the bottom side of the substrate when the removable pad covering is stripped away, or the remainder portion can be removed along with the removable pad covering. In other embodiments, the pad coverings can be permanent. For example, when the test pads are needed for a test procedure, the test pads can be accessed via exposed isolation features that are configured to separate the pad coverings from the surrounding substrate.

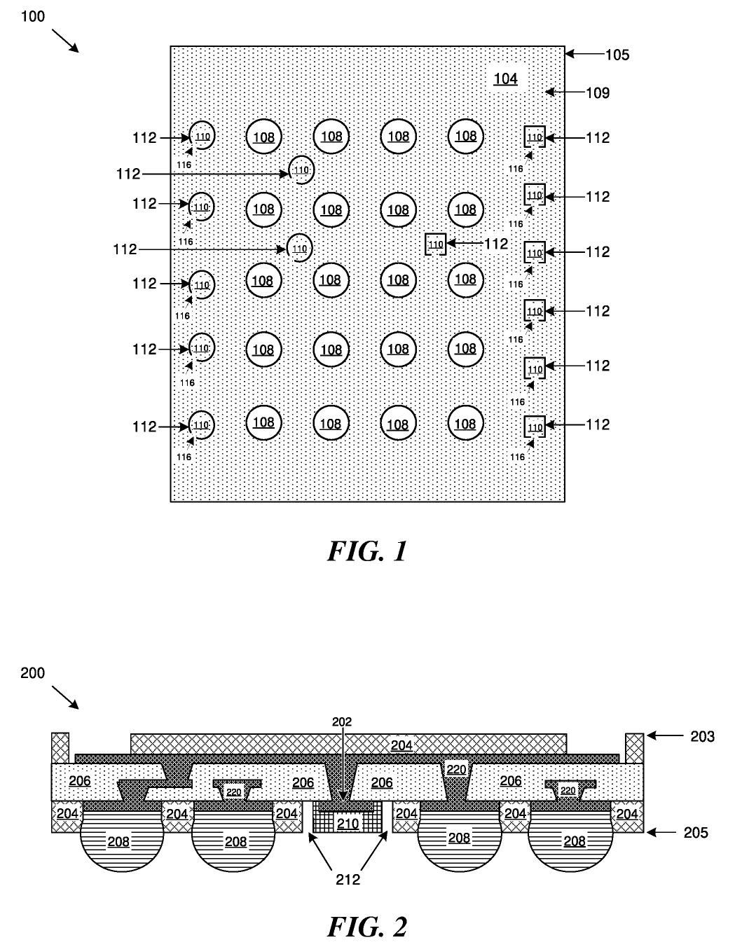

FIG. 1 is a simplified schematic partial plan view of a semiconductor device assembly 100 configured in accordance with various embodiments of the present technology. As shown, the assembly 100 includes a substrate 104 made of a dielectric material and having a surface 105 (e.g., bottom surface, top surface). In the illustrated embodiment, the assembly 100 further includes a plurality of external contacts 108 that are each exposed through the surface 105 of the substrate 104. For example, the plurality of external contacts 108 can be a ball grid array (BGA). The external contacts 108 are optional, and one or more of the external contacts 108 shown in FIG. 1 can be omitted in other embodiments of the present technology.

The assembly 100 of FIG. 1 further includes one or more pads (e.g., one or more test pads) disposed in or beneath the surface 105 of the substrate 104. The pad(s) is/are not visible in FIG. 1, as the assembly 100 also includes a protective layer 109 that is disposed atop the pad(s). As shown, the protective layer 109 includes one or more removable pad coverings 110. Each removable pad covering 110 can have a shape (e.g., square, circular, or rectangular). The shape of a removable pad covering 110 can be fully or partially defined by a corresponding isolation feature 112 (e.g., one or more trenches, voids, recesses, moats, indentations) of the assembly 100 that fully or partially surrounds the removable pad covering 110. In some embodiments, the shape of a removable pad covering 110 can match a shape of an underlying pad. For example, a pad of the assembly 100 can have a first shape, the corresponding removable pad covering 110 can have a second shape, and the second shape can match the first shape. Alternatively, the first shape of the pad can be different from the second shape of the removable pad covering 110 disposed atop it. The pad covering can be disposed over at least a portion of a bottom surface of the underlying pad such that at least the portion of the bottom surface is unexposed through the bottom side of the substrate.

Each isolation feature 112 can separate a corresponding removable pad covering 110 from the substrate 104. Additionally, or alternatively, each isolation feature 112 can be used (e.g., as an access point) for selectively separating the removable pad covering 110 from the substrate 104. As shown in FIG. 1, the separation between a removable pad covering 110 and the substrate 104 can be partial, such as when a corresponding isolation feature 112 does not fully surround, or form a complete shape about, the removable pad covering 110. In such embodiments, the protective layer 109 can include a remainder 116 that connects the removable pad covering 110 to the substrate 104 and/or to one or more other removable pad coverings 110 of the protective layer 109. In at least some of these embodiments, the removable pad covering 110 can be configured as a flap. Thus, when the removable pad covering 110 is separated from the substrate 104 (e.g., to expose an underlying pad through the substrate 104), the remainder 116 can maintain the removable pad covering 110 in contact with the substrate 104 and/or the one or more other removable pad coverings 110 of the protective layer 109, thereby facilitating quick realigning and/or repositioning of the removable pad covering 110 over the underlying pad. In some embodiments, the remainder 116 can be torn or broken, such as to fully separate the removable pad covering 110 from the substrate 104 or the rest of the protective layer 109.

FIG. 2 is a cross-sectional side view of a semiconductor device assembly 200 configured in accordance with various embodiments of the present technology. As shown, the assembly 200 includes a substrate 204 formed at least in part of a dielectric material. The substrate 204 includes a top surface 203 (and associated top side) and a bottom surface 205 (and associated bottom side). In some embodiments, the assembly 200 can further include a reinforcement layer 206 formed within the substrate 204. The reinforcement layer 206 can comprise a prepreg material. For example, the prepreg material can be a composite material formed by pre-impregnating a reinforcing fabric (e.g., fiberglass, carbon fiber, or aramid) with a resin system (e.g., a thermoset polymer, such as epoxy, which is partially cured to a tacky state).

The assembly 200 is further shown as including an interconnect network having a plurality of conductive pathways 220 that extend within and throughout the substrate 204 and the reinforcement layer 206. The assembly 200 also includes a pad 202 (e.g., a test pad, a bond pad) exposable through the substrate 104. The pad 202 can comprise a metal (e.g., copper) or a metal alloy. In some embodiments, the pad 202 can be part of the interconnect network. In some embodiments, the assembly 200 can further include exposed bonding locations 208 (e.g., solder bumps, pillars, balls) formed at the bottom surface 205 of the substrate 204 and laterally adjacent the pad 202, as illustrated by FIG. 2. The exposed bonding locations 208 can be free from any covering.

In the illustrated embodiment, a removable pad covering 210 is disposed over the pad 202. The removable pad covering 210 is flanked by an isolation feature 212 that separates the removable pad covering 210 from the substrate 204. In some embodiments, at least when the removable pad covering 210 is disposed over the pad 202, the isolation feature 212 comprises an open trench having (a) first sidewalls at least partially defined by the substrate 204 and (b) second sidewalls at least partially defined by the removable pad covering 210. The open trench can extend a depth into the substrate 204, such as (i) to a depth corresponding to a position of the pad 202 within the substrate 204 and/or (ii) to a depth at which the reinforcement layer 206 is exposed at a bottom of the open trench. As a specific example, the pad 202 can include a bottom surface, a top surface on a side of the pad 202 opposite the bottom surface 205 of the substrate 204, and sidewalls extending between the bottom surface and the top surface. Continuing with this example, the open trench can extend from the bottom surface 205 of the substrate 204 toward the top surface 203 of the substrate 204, and to a plane that is (a) generally parallel with the bottom surface of the pad 202 and (b) positioned within the substrate 204 (i) at the bottom surface of the pad 202 or (ii) at a location between the bottom surface of the pad 202 and the top surface 203 of the substrate 204. In some embodiments, the open trench is a product of an etching process. The open trench can also be the result of a lamination process, in which case the open trench comprises a remaining portion of a non-solder-mask-defined opening that has been partially filled with solder mask.

In some embodiments, the removable pad covering 210 can cover the bottom surface of the pad 202 and leave the sidewalls of the pad 202 exposed through the bottom surface 205 of the substrate 204 via the open trench of the isolation feature 212. Alternatively, as shown in FIG. 2, the removable pad covering 210 can cover the bottom surface of the pad 202 and extend down the sidewalls of the pad 202. In other words, the removable pad covering 210 can envelope portions of the pad 202 that can be exposed through the bottom surface 205 of the substrate 204. Thus, at least while the removable pad covering 210 is disposed over the pad 202, exposure of the pad 202 to air can be reduced, minimized, or eliminated. As a result, the risk of oxidation of the pad 202 (or of galvanic corrosion) can be reduced, minimized, or eliminated.

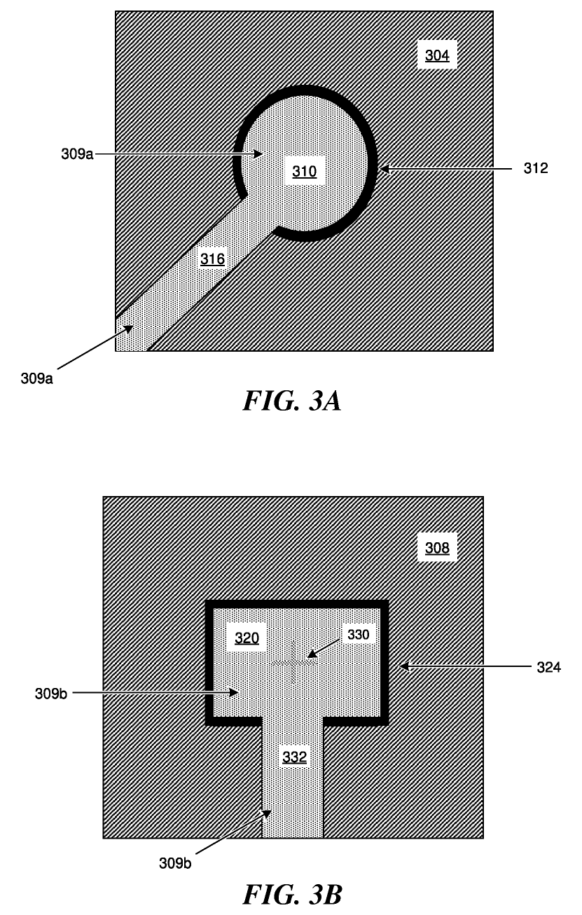

FIG. 3A is a simplified detail view of a removable pad covering 310 configured in accordance with various embodiments of the present technology. The removable pad covering 310 is positioned over a pad (not shown), which is disposed in a substrate 304. As shown, the removable pad covering 310 is generally circular or ovular. The removable pad covering 310 is partially separated from the substrate 304 by an isolation feature 312. The removable pad covering 310 can be part of a protective layer 309a. The protective layer 309a can include an area that extends beyond (or is not positioned over) the pad. For example, the protective layer 309a can include a remainder portion 316 (also referred to herein as a “connector portion” or a “connective portion”), and the removable pad covering 310 can be configured as a flap. The remainder portion 316 of the protective layer 309a can connect the removable pad covering 310 to the substrate 304 and/or to one or more other removable pad coverings of the protective layer 309a.

In some embodiments, the protective layer 309a comprises a solder mask, and the substrate 304 comprises the same solder mask. In these and other embodiments, the protective layer 309a can be coplanar with a surface of the substrate 304. Additionally, or alternatively, the protective layer 309a and the substrate 304 can be the result of the same step of a lamination process.

FIG. 3B is simplified detail view of another removable pad covering 320 configured in accordance with various embodiments of the present technology. The alternative removable pad covering 320 is positioned over a pad (not shown), which is disposed in a substrate 308. As shown, the removable pad covering 320 can have a shape (e.g., a rectangle, or a square) that is different from the shape of the removable pad covering 310 of FIG. 3A. The shape of the removable pad covering 320 is at least partially delineated by an isolation feature 324 (e.g., a trench). In the illustrated embodiment, the isolation feature 324 partially surrounds the removable pad covering 320. In other embodiments, the isolation feature 324 can fully surround the removable pad covering 320.

Similar to the removable pad covering 310 of FIG. 3A, the removable pad covering 320 of FIG. 3B can be part of a protective layer 309b that also includes a remainder portion 332 (also referred to herein as a “connector portion” or a “connective portion”) attached to the removable pad covering 320 such that the removable pad covering 320 is configured as a flap. The remainder portion 332 can connect the removable pad covering 320 to the substrate 308 and/or to one or more other removable pad coverings of the protective layer 309b.

In some embodiments, the protective layer 309b comprises a solder mask, and the substrate 308 comprises the same solder mask. In these and other embodiments, the protective layer 309b can be coplanar with a surface of the substrate 308. Additionally, or alternatively, both the protective layer 309b and the substrate 308 can be the result of the same step of a lamination process.

In some implementations, the protective layer 309a of FIG. 3A and/or the protective layer 309b of FIG. 3B include a marker. For example, the protective layer 309b is illustrated with a marker 330. The marker 330 can be positioned on the removable pad covering 320 (as shown in FIG. 3B), or the marker 330 can be positioned on the remainder portion 332 or on the substrate 308. The marker 330 is configured to aid visual identification of the removable pad covering 320 and distinguish it from the substrate 308. For example, the marker 330 can be a fiducial. The fiducial can be usable to visually identify a location of the pad covering 320 and distinguish it from the substrate 308. In some implementations, the marker 330 includes a layer of solder mask material comprising a first color that is different from a second color of the substrate 308.

Referring to FIGS. 3A and 3B together, the isolation features 312, 324 can be positioned on opposite sides of the remainder portions 316, 332, respectively. For example, the isolation features 312, 324 can begin at a first side of the respective remainder portion 316, 332, extend at least partially or partway along a perimeter of the respective removable pad covering 310, 320, and/or end at a second side of the respective remainder portion 316, 332 opposite the first side. In some implementations, the isolation features 312, 324 delineate the shapes of the removable pad coverings 310, 320 but for a width of the remainder portions 316, 332.

As discussed above, the removable pad covering 310 of FIG. 3A and/or the removable pad covering 320 of FIG. 3B each belong to a protective layer 309a, 309b, respectively. The protective layer 309a and/or the protective layer 309b can each include a plurality of removable pad coverings (including the removable pad covering 310, 320, respectively). As a specific example, the protective layer 309a can be the protective layer 309b, and the removable pad covering 310 can be connected to the removable pad covering 320 via the protective layer 309a/309b. Thus, the removable pad covering 310 can be disposed over a first pad of an assembly, and the removable pad covering 320 can be disposed over a second pad of the assembly that is different from the first pad. The second pad can be laterally offset from the first pad. In at least some embodiments that employ a protective layer having a plurality of removable pad coverings, the protective layer can be configured to enable the removal of all removable pad coverings of the protective layer from an assembly in a single step, such as by manually removing the protective layer (e.g., by hand) and thereby pulling removable pad coverings of the protective layer away from the assembly.

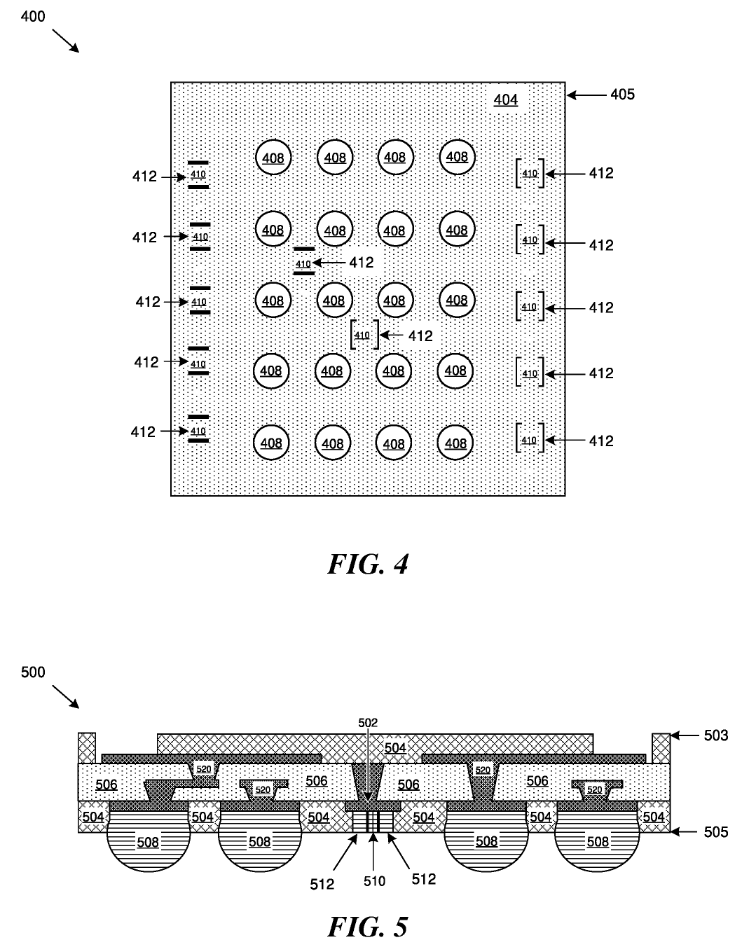

FIG. 4 is a simplified schematic partial plan view of another semiconductor device assembly 400 configured in accordance with various embodiments of the present technology. As shown, the assembly 400 includes (a) a substrate 404 with a surface 405 (e.g., bottom surface, top surface, exterior surface), and (b) one or more pads disposed in the substrate 404 beneath the surface 405. The pad(s) is/are not visible in FIG. 4 because one or more pad coverings 410 is/are disposed over the pad(s). The assembly 400 also includes one or more isolation features 412 that is/are configured to separate at least part of the pad covering(s) 410 from the substrate 404.

As illustrated in FIG. 4, the assembly 400 can optionally include one or the exposed external contacts 408. For example, the assembly 400 can include a plurality of external contacts 408 arranged as a ball grid array (BGA).

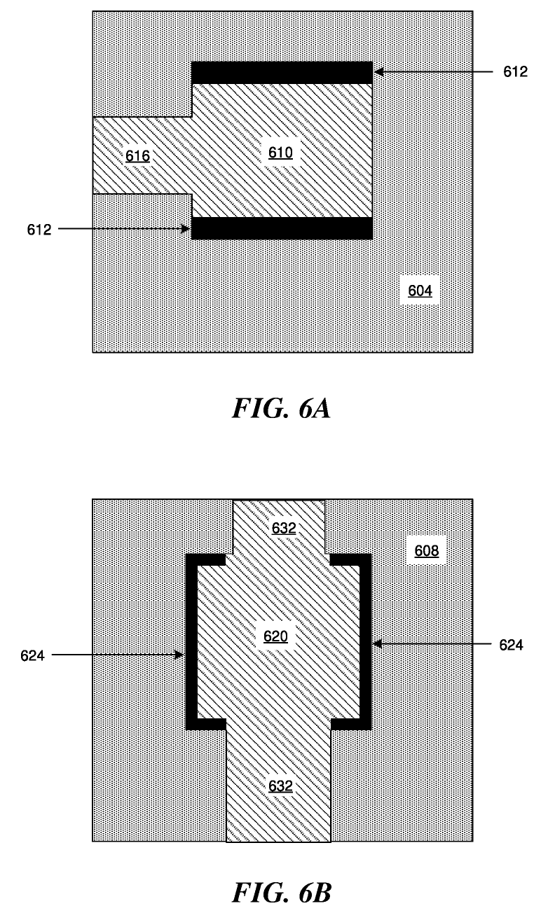

FIG. 5 is a cross-sectional side view of a semiconductor device assembly 500 configured in accordance with various embodiments of the present technology. As shown, the assembly 500 includes a substrate 504 having a top surface 503 (and associated top side) and a bottom surface 505 (and associated bottom side). The assembly 500 can further include (a) an internal layer 506 (e.g., comprising a reinforcement material, such as prepreg) and/or (b) conductive structures 520 (e.g., RDLs, vias, lines, traces, or pads).

The assembly 500 further includes a pad 502 (e.g., a test pad, a bond pad) disposed between the top surface 503 and the bottom surface 505 of the substrate 504, and beneath a pad covering 510 and an isolation feature 512. The pad 502 can comprise a metal (e.g., copper) or a metal alloy. The pad 502 can be connected to the conductive structures 520. In some embodiments, the pad 502 is comprised by the conductive structures 520. In some embodiments, the assembly 500 can also include exposed bonding locations 508 (e.g., solder bumps, pillars, balls) formed at the bottom surface 505 of the substrate 504 and laterally adjacent to the test pad 502, as illustrated by FIG. 5. The exposed bonding locations 508 can be free from any covering.

The isolation feature 512 can at least partially surround the pad covering 510 and at least partially separate the pad covering 510 from the substrate 504. As illustrated, the isolation feature 512 can include multiple isolation components (e.g., barriers) that flank the pad covering 510 and at least partially separate the pad covering 510 from the substrate 504. For example, the isolation feature 512 can comprise a trench of plated metal. The trench of plated metal can comprise an alloy (e.g., gold-nickel, gold-cobalt, palladium-nickel, tin-silver, or tin-bismuth). Gold-nickel can provide greater durability and resistance to wear; cobalt alloys can provide greater thermal stability. Palladium alloys can improve the solderability of surfaces. Tin-silver can provide greater thermal conductivity and dissipation of heat, while tin-bismuth can provide resistance to electromagnetic interference. Additionally, or alternatively, the trench of plated metal can comprise a pure metal, where it is desirable or practicable (e.g., gold, for superior conductivity and corrosion resistance; silver, for low electrical resistance; palladium, cost-effective alternative to gold; tin, for preventing signal degradation; or nickel, for its evenness and chemical resistance). The trench of plated metal can have a first color. The first color can be distinct and visible against a second color of the substrate 504. In such embodiments, the first color of the trench of plated metal can make the pad covering 510 more visible. In some implementations, the trench of plated metal can be configured to assist a machine identify (e.g., using a visual sensor) the pad 502 beneath the pad covering 510 (e.g., for a test procedure).

As illustrated in FIG. 5, isolation feature 512 (e.g., the trench of plated metal) is disposed over the pad 502, and laterally adjacent the pad covering 510. In some embodiments, a bottom surface of the isolation feature 512 (e.g., the bottom surface of the trench of plated metal) can be in contact with the pad 502, and an upper area of the isolation feature 512 (e.g., an upper area of the trench of plated metal) can be exposed. In some embodiments, the upper area of the isolation feature 512 projects beyond the bottom surface 505 of the substrate 504 in a direction away from the assembly 500. Alternatively, the upper area of the isolation feature 512 can be coplanar with the bottom surface 505 of the substrate 504, or they can be raised with respect to the surface 505 of the substrate in a direction away from the substrate. The isolation feature 512 (e.g., the trench of plated metal) can protect the underlying pad 502 from oxidation, while still providing a means of accessing the pad (e.g., with a test probe). Accessing the pad can include peeling the pad covering away.

In some embodiments, the isolation feature 512 (e.g., the trench of plated metal) can be a product of plating an open trench (e.g., the open trench of the isolation feature 212 illustrated in FIG. 2) or similar structures. In these and other embodiments, the pad covering 510 can be a result of a lamination process. As a specific example, the pad covering 510 and/or the substrate 504 can be placed on the assembly 500 as part of a lamination process performed prior to plating. Prior to lamination and plating, an opening can exist above the pad 502. The opening can comprise a solder mask defined (SMD) opening. Vestiges of the SMD opening can remain, and can be visible in the assembly 500. For example, the pad 502 can be set at a location between the bottom surface 505 and the top surface 503 of the substrate 504, and can include a first width that is greater than a second width of the corresponding pad covering 510 and/or the isolation feature 512 that is/are disposed over the pad 502.

FIG. 6A is a simplified detail view of a pad covering 610 configured in accordance with various embodiments of the present technology. As shown, the pad covering 610 is at least partially separated from a substrate 604 by an isolation feature 612 (e.g., a trench of plated metal). The pad covering 610 also includes or is connected to a remainder portion 616 (also referred to herein as a “connector portion” or a “connective portion”) that connects the pad covering 610 to the substrate 604 and/or to other portions of a protective layer. For example, a protective layer can include a plurality of pad coverings (including the pad covering 610) and a plurality of corresponding remainder portions (including the remainder portion 616), and the remainder portion 616 can attach the pad covering 610 to the substrate 604 and/or or to another pad covering (not shown) of the protective layer.

In some embodiments, the isolation feature 612 can be positioned on a single side of the pad covering 610. In other embodiments, the isolation feature 612 can be positioned on multiple sides of the pad covering 610. As a specific example, the isolation feature 612 is shown in FIG. 6A as including two components that are positioned on opposite side of (and arranged to bracket) the pad covering 610. The pad covering 610 of FIG. 6A can be positioned over a bond pad, a metal line, a through-silicon via (TSV), a microbump, a BGA ball, a wire bond, a redistribution layer (RDL), a contact pad, or another conductive structure.

FIG. 6B is a simplified detail view of another pad covering 620 configured in accordance with various embodiments of the present technology. The pad covering 620 is at least partially separated from a substrate 608 by an isolation feature 624 (e.g., a metal trench, such as a trench of plated metal). The pad covering 620 also includes or is connected to a remainder portion 632 (also referred to herein as a “connector portion” or a “connective portion”) that connects the pad covering 620 to the substrate 608 and/or to other portions of a protective layer. For example, a protective layer can include a plurality of pad coverings (including the pad covering 620) and a plurality of corresponding remainder portions (including the remainder portion 632), and the remainder portion 632 can attach the pad covering 620 to the substrate 608 and/or or to another pad covering (not shown) of the protective layer. As a specific example, the reminder portion 632 can be (or be connected to) the remainder portion 616 of FIG. 6A such that the remainder portions 616, 632 belong to a same protective layer and/or are connected to one another. As shown in FIG. 6B, the remainder portion 632 includes two sections that are arranged at different (e.g., opposite) sides of the pad covering 620. The two sections of the remainder portion 632 can attach the pad covering 620 to the substrate 608 and/or to one or more other pad coverings (not shown).

As further illustrated by FIG. 6B, the isolation feature 624 can include two components (e.g., two metal trenches). The two components can be arranged at different (e.g., opposite) sides of the pad covering 620. Thus, the two components can be configured to separate the pad covering 620 the different sides from the substrate 608. In some implementations, the isolation feature 624 can be aligned with a center of the pad covering 620, and the two sections of the remainder portion 632 can attach the pad covering 620 to the substrate 608 and/or to one or more other pad coverings at different (e.g., opposite) sides of the centrally aligned isolation feature 624.

In some implementations, the pad covering 610 of FIG. 6A and/or the pad covering 620 of FIG. 6B include a marker (e.g., fiducial). The marker can be positioned on the pad covering(s) 610, 620, or the marker can be positioned on the remainder portion(s) 616, 632 or the substrate(s) 604, 608. The marker can be configured to aid visual identification of the pad covering(s) 610, 620 and distinguish it/them from the substrate(s) 604, 608, respectively.

Although the semiconductor device assembly embodiments illustrated and described above with reference to FIGS. 1-6B are shown as including a single semiconductor device, such semiconductor device assemblies can be provided with additional semiconductor devices in further embodiments of the present technology. For example, the single semiconductor devices illustrated in FIGS. 1, 2, 3A, 3B, 4, 5, 6A and/or FIG. 6B can be implemented in, for example, semiconductor device assemblies that include a vertical stack of semiconductor devices, a plurality of semiconductor devices, mutatis mutandis.

In some embodiments, the semiconductor devices illustrated in the assemblies of FIGS. 1-6B could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In these and other embodiments, the semiconductor dies of the assemblies illustrated and described above could be logic dies (e.g., controller dies, processor dies, etc.), or a mix of logic and memory dies (e.g., a memory controller die and a memory die controlled thereby).

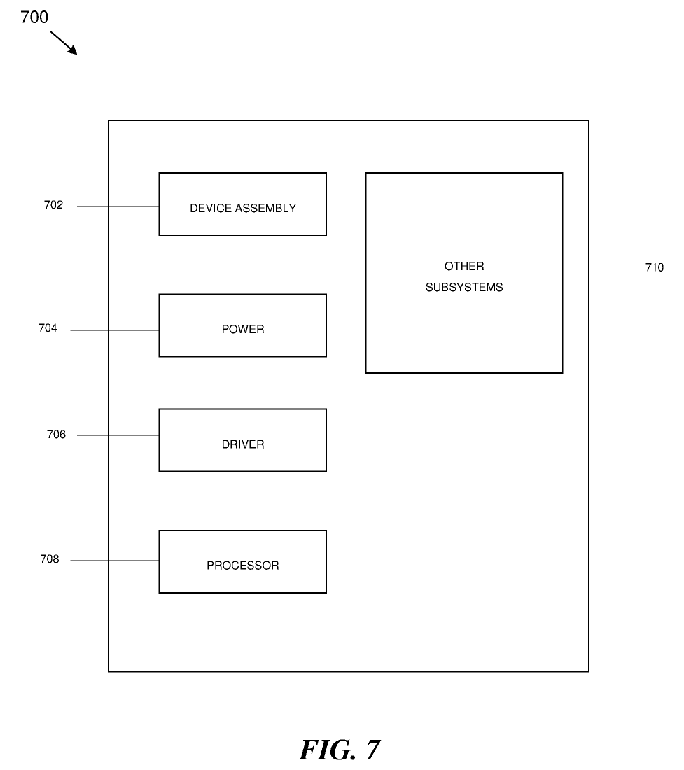

Any one of the semiconductor devices and semiconductor device assemblies described above with reference to FIGS. 1-6B can be incorporated into any of a myriad of larger and/or more complex systems, a representative example of which is system 700 shown schematically in FIG. 7. The system 700 can include a semiconductor device assembly 702 (or a discrete semiconductor device), a power source 704, a driver 706, a processor 708, and/or other subsystems or components 710. The semiconductor device assembly 702 can include features generally similar to those of the semiconductor devices described above with reference to FIGS. 1-6B. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 700 may be housed in a single unit or distributed over multiple, interconnected units (e.g., through a communications network). The components of the system 700 can also include remote devices and any of a wide variety of computer readable media.

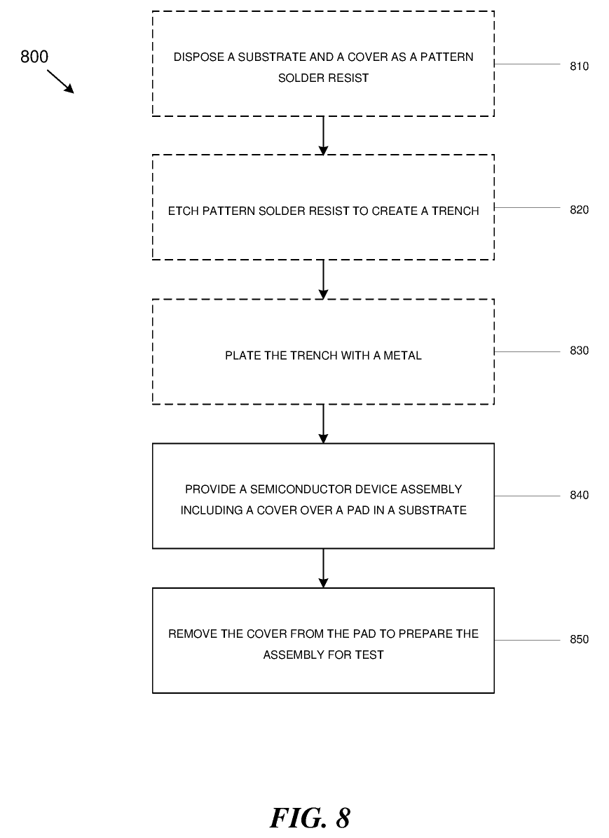

FIG. 8 is a flow chart illustrating a method 800 of making a semiconductor device assembly. In some implementations of the method 800, the method includes disposing a substrate and a cover as a pattern solder resist (box 810). The substrate and the cover can be connected. In some implementations, the substrate and the cover are disposed such that the cover is positioned on a pad in a surface of a substrate. Providing the semiconductor device assembly can also include etching the pattern solder resist to create a trench (box 820). The trench can be in the substrate. In some implementations, the trench at least partially separates the cover from the substrate. In some implementations, etching the pattern solder resist includes etching the cover to form a marker (e.g., a fiducial). For example, the marker can be configured to aid visual identification of the cover and distinguish it from the substrate.

Providing the semiconductor device assembly can also include plating the trench with a metal (box 830). In some implementations, the metal is in contact with the pad, and an upper area of the metal is exposed at or above a surface of the substrate. Additionally, the pad can be covered by both the cover and the metal.

The method 800 includes providing a semiconductor device assembly, including a cover over a pad in a substrate (box 840). The cover can comprise (i) a pad covering or (ii) a removable pad covering disposed over/atop the pad, and the pad can be disposed beneath a surface of the substrate (e.g., the pad can be embedded within the substrate). The cover can be at least partially surrounded by a barrier (e.g., a trench, or a plated metal structure). The barrier can at least partially separate the cover from the substrate. The method 800 further includes removing the cover from the pad to prepare the assembly for test (box 850). Additionally, removing the cover can expose at least a portion of the pad for probing or other connections.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate having a top side and a bottom side opposite the top side;
a pad disposed within the substrate at a location between the top side and the bottom side, the pad accessible via the bottom side of the substrate;
a protective layer at the bottom side of the substrate, the protective layer including a pad covering disposed over at least a portion of a bottom surface of the pad such that at least the portion of the bottom surface is unexposed through the bottom side of the substrate; and
an isolation feature at the bottom side of the substrate and configured to separate at least a portion of the pad covering from the substrate.

2. The semiconductor device assembly of claim 1, wherein the pad covering is a removable pad covering that is configured to be stripped away from the bottom side of the substrate to expose at least the portion of the bottom surface of the pad through the bottom side of the substrate.

3. The semiconductor device assembly of claim 2, wherein:
the pad further includes (i) a top surface on a side of the bottom surface opposite the bottom side of the substrate, and (ii) sidewalls extending between the top surface and the bottom surface; and
at least when the removable pad is disposed over the portion of the bottom surface of the pad, the removable pad covering envelopes the bottom surface and at least a portion of the sidewalls of the pad.

4. The semiconductor device assembly of claim 2, wherein the isolation feature includes an open trench that extends at least partway about a perimeter of the removable pad covering.

5. The semiconductor device assembly of claim 4, wherein:
the pad further includes (i) a top surface on a side of the bottom surface that is opposite the bottom side of the substrate, and (ii) sidewalls extending between the top surface and the bottom surface; and
at least when the removable pad is disposed over the portion of the bottom surface of the pad, the removable pad covering is disposed over the bottom surface of the pad such that at least a portion of the sidewalls of the pad is exposed via the bottom side of the substrate and the open trench.

6. The semiconductor device assembly of claim 4, wherein the substrate comprises a reinforcement layer between the top side and the bottom side of the substrate, and wherein the open trench extends a depth into the substrate from the bottom side of the substrate such that the reinforcement layer is exposed within the open trench.

7. The semiconductor device assembly of claim 2, wherein the protective layer further comprises a remainder portion connected to the removable pad portion such that the removable pad covering is configured as a flap that is reversibly strippable away from the bottom side of the substrate.

8. The semiconductor device assembly of claim 1, wherein:
the pad is a first pad, the location is a first location, and the pad covering is a first pad covering;
the semiconductor device assembly further comprises a second pad disposed within the substrate at a second location (a) between the top side and the bottom side of the substrate, and (b) laterally offset from the first pad;
the second pad is accessible via the bottom side of the substrate; and
the protective layer further includes (i) a second pad covering disposed over at least a portion of a bottom surface of the second pad such that at least the portion of the bottom surface of the second pad is unexposed through the bottom side of the substrate, and (ii) a remainder portion connecting the second pad covering to the first pad covering.

9. The semiconductor device assembly of claim 1, wherein the pad has a first shape, wherein the pad covering has a second shape at least partially delineated by the isolation feature, and wherein the second shape of the pad covering matches the first shape of the pad.

10. The semiconductor device assembly of claim 1, wherein the pad has a first shape, wherein the pad covering has a second shape at least partially delineated by the isolation feature, and the second shape of the pad covering is different from the first shape of the pad.

11. The semiconductor device assembly of claim 1, wherein the protective layer includes a marker configured to aid visual identification of a location of the pad along the bottom side of the substrate.

12. The semiconductor device assembly of claim 1, wherein the pad comprises a test pad for use in a testing procedure of the semiconductor assembly.

13. The semiconductor device assembly of claim 1, further comprising exposed bonding locations at the bottom side of the substrate, wherein the exposed bonding locations are laterally offset from the pad.

14. The semiconductor device assembly of claim 1, wherein the protective layer further includes a connection to the substrate, wherein the protective layer and the substrate are formed at least in part of a solder mask, and wherein the protective layer is coplanar with a surface at the bottom side of the substrate.

15. The semiconductor device assembly of claim 10, wherein the isolation feature comprises a trench of plated metal, wherein the trench of plated metal is disposed laterally adjacent to the pad covering, wherein the plated metal is in contact with the pad, and wherein an upper area of the plated metal is exposed at the bottom side of the substrate such that the pad is accessible from the bottom side of the substrate via the plated metal.

16. The semiconductor device assembly of claim 15, wherein the protective layer further includes a remainder portion having two sections connected to opposite sides of the pad covering from one another, wherein the trench of plated metal is a first trench of plated metal, wherein the isolation feature further comprises a second trench of plated metal, and wherein first and second trenches of plated metal are disposed centrally over the pad at different sides of the pad covering from one another.

17. A semiconductor device assembly, comprising:
a substrate having a first side, a second side opposite the first side, and an exterior surface at the first side;
a conductive structure (i) positioned at a first location between the first side and the second side and (ii) recessed within the first side of the substrate with respect to the exterior surface, wherein the conductive structure is selectively accessible via the first side;
a covering disposed at the first side of the substrate and atop the conductive structure such that at least a portion of the conductive structure is unexposed through the first side of the substrate; and
an isolation feature formed at the first side of the substrate at a second location (a) between the conductive structure and the exterior surface at the first side, and (b) laterally offset from the covering.

18. A method, comprising:
providing a semiconductor device assembly, the semiconductor assembly including—
a substrate having a first side, a second side opposite the first side, and a surface at the first side,
a pad disposed within the substrate at a location (a) between the first side and the second side, and (b) recessed within the first side of the substrate with respect to the surface,
a pad covering disposed over at least a portion of the pad such that at least the portion of the pad is unexposed through the first side of the substrate, and
an isolation feature formed at the first side of the substrate and separating at least a portion of the pad covering from the substrate; and
accessing the pad, wherein accessing the pad includes (a) peeling the pad covering away from the pad such that at least the portion of the pad is exposed through the first side of the substrate, or (b) accessing the pad via the isolation feature while the pad covering is disposed over at least the portion of the pad.

19. The method of claim 18, wherein providing the semiconductor device assembly further includes:
disposing the substrate and the pad covering as a pattern solder resist; and
etching the pattern solder resist to create a trench at the first side of the substrate such that the pad covering is positioned atop the pad.

20. The method of claim 19, wherein providing the semiconductor device assembly further includes:
plating the trench with a metal alloy, such that (a) the metal alloy is in contact with the pad and (b) an upper area of the metal alloy is (i) exposed at the first side of the substrate and (ii) planar with the surface of the substrate or raised with respect to the surface of the substrate in a direction away from the substrate; and/or
etching the pad covering to form a fiducial at the first side of the substrate that is usable to visually identify a location of the pad covering and distinguish it from the substrate.
